(19) United States
(12) Patent Application Publication
(10) Pub. No.: US 2014/0150843 A1
(43) Pub. Date: Jun. 5, 2014

(54) SHINGLE-LIKE PHOTOVOLTAIC MODULES

(71) Applicants: David B. Pearce, Saratoga, CA (US); Dennis R. Hollars, San Jose, CA (US); Robert J. Cleereman, Midland, MI (US)

(72) Inventors: David B. Pearce, Saratoga, CA (US); Dennis R. Hollars, San Jose, CA (US); Robert J. Cleereman, Midland, MI (US)

(73) Assignee: NUVOSUN, INC., Milpitas, CA (US)

(21) Appl. No.: 14/008,909

(22) PCT Filed: Mar. 30, 2012
(86) PCT No.: PCT/US12/31702

§ 371 Date: Feb. 21, 2014

Related U.S. Application Data
(60) Provisional application No. 61/516,274, filed on Apr. 1, 2011.

(51) Int. Cl. H01L 31/048; H01L 31/0203

(52) U.S. Cl. CPC H01L 31/0483; H01L 31/0203
USPC 136/244; 438/80

(57) ABSTRACT

A photovoltaic system comprises one or more shingle-like photovoltaic (PV) modules, each having a layer of optically transparent material adjacent to a layer of photoactive material configured to generate electricity upon exposure to light from the layer of optically transparent material. In some cases the layer of optically transparent material of each of the one or more shingle-like PV modules has a pattern of depressions in a shingle-like configuration.

### CROSS-REFERENCE

This application claims the benefit of U.S. Provisional Application No. 61/516,274, filed Apr. 1, 2011, which application is entirely incorporated herein by reference.

### BACKGROUND OF THE INVENTION

Current photovoltaic (PV) modules may utilize crystalline silicon cells packaged with a low iron tempered glass top sheet, a TPE (Tedlar®, polyester, EVA) back sheet, an extruded aluminum frame, and a junction box with cables to connect to adjacent modules. The modules are mounted to a metal support structure that is typically secured with roof penetrating screws, which is undesirable due to the high risk of water leaks. In addition, an array of modules and the associated mounting structures can be heavy, and in some cases standard roofing structures will not support the added weight without remedial bracing.

Building integrated photovoltaic (BIPV) are materials that are used to replace conventional building materials in parts of building envelopes, such as roofs, skylights, or facades. An advantage of integrated photovoltaics over more common non-integrated systems is that the initial cost of installation can be offset by reducing the amount spent on building materials and labor that would be normally used to construct the part of the building that the BIPV modules replace. An example of BIPV is solar cells integrated into roofing structures, which serve as both photoelectric devices and roofing materials. While these products provide some of the functions of conventional roofing structures, they do not provide an integrated solution in terms of function and appearance that is desirable in residential roofing.

BIPV's may be housed in bulky structures, or structures that do not provide adequate support to minimize photovoltaic cell breakage during installation. The bulkiness of some current frames may lead to increased manufacturing costs, both from a materials perspective and processing perspective, and the cost associated with transporting and installing the BIPV's.

### SUMMARY OF THE INVENTION

In view of the limitations of current photovoltaic (PV) modules, recognized herein is the need for photovoltaic (PV) modules and systems that provide seamless integration into residential PV installations, such as shingle roofing installations, while simultaneously providing a structural function, such as a roofing function.

The invention provides solar photovoltaic modules for the production of solar electricity. The invention discloses large area PV (or solar) module shingle-like roofing modules and systems that can be readily used with, or integrated with, conventional roofing shingles to produce a lightweight, functional and visually compatible alternative to conventional solar module installations.

An aspect of this invention provides a shingle-like solar module roofing system that is economical and requires reduced labor to install.

Another aspect of the invention provides a shingle-like solar module roofing system that requires no penetrations of the existing roof structure.

Another aspect of the invention provides a large area shingle-like solar module roofing system that is much lighter in weight than conventional PV module arrays.

Another aspect of the invention provides a photovoltaic module comprising a first layer of an optically transparent material that is transparent to at least a portion of incident light, and a second layer of a water vapor barrier material adjacent to the first layer, wherein the second layer is transparent to at least a portion of light from the first layer. The PV module includes a third layer having one or more interconnected photovoltaic (PV) cells adjacent to the second layer, wherein the one or more interconnected PV cells generate power upon exposure to light directed from the first layer through the second layer to the third layer, and a fourth layer of an electrically insulating material adjacent to the third layer. The first layer can include one or more outer surfaces that are oriented at an angle greater than zero degrees in relation to a surface of the second layer adjacent to the first layer. In some cases, the first layer is formed from a single substrate that is embossed to provide a pattern of depressions in a shingle-like configuration.

Another aspect of the invention provides a photovoltaic module comprising a first layer of an optically transparent material that is transparent to at least a portion of incident light, and a second layer of a first moisture barrier material adjacent to the first layer, wherein the second layer is transparent to at least a portion of light from the first layer. The first layer has a pattern of depressions, which in some cases are in a shingle-like configuration. The PV modules further comprises a third layer having one or more interconnected photovoltaic (PV) cells adjacent to the second layer, wherein the one or more interconnected PV cells generate power upon exposure to light from the second layer, and a fourth layer of an electrically insulating material adjacent to the third layer. In some cases, the photovoltaic module can have a non-uniform thickness along an axis oriented from a first side to a second side of the photovoltaic module. In some cases, the first layer has a non-uniform thickness along the axis oriented from the first side to the second side of the PV module.

Another aspect of the invention provides a photovoltaic system comprising one or more shingle-like photovoltaic modules, each shingle-like photovoltaic module of the one or more shingle-like photovoltaic modules having an embossed layer of optically transparent polymeric material (e.g., PMMA) adjacent to a layer of photoactive material that is configured to generate electricity upon exposure to light from the embossed layer. In some cases, the embossed layer of optically transparent polymeric material can have at least one outer surface that is angled greater than 0° in relation to a surface between the layer of the optically transparent material and the layer of photoactive material. In some cases, the system further includes a shingle, such as a non-PV shingle, adjacent to an individual shingle-like PV module of the one or more shingle-like PV modules.

Another aspect of the invention provides a method for forming a shingle-like photovoltaic module, comprising providing a layer of photoactive material adjacent to an optically transparent polymeric sheet having a pattern of depressions formed therein in a shingle-like configuration. The photoactive material generates electricity upon exposure to light from the optically transparent polymeric sheet. In an embodiment, prior to providing the layer of photoactive material, the pattern of depressions is formed in the optically transparent polymeric sheet. The pattern of depressions can be formed by embossing.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 is a large scale perspective schematic view of the shingle-like appearance solar module, in accordance with an embodiment of the invention;

FIG. 2 is a schematic side-view of a portion of the shingle-like appearance solar module of FIG. 1, in accordance with an embodiment of the invention;

FIG. 3 is a schematic side-view of the PV module of FIG. 1, showing the top and bottom regions of the shingle-like appearance solar module, in accordance with an embodiment of the invention;

FIG. 4 is a schematic cross-sectional side view of two representations (A and B) of the ridge line of a roof showing installations of the shingle-like appearance module with wiring, in accordance with an embodiment of the invention;

FIG. 5 shows an outer surface of the PV module of FIG. 1, in accordance with an embodiment of the invention;

FIG. 6 schematically illustrates a photovoltaic (PV) module, in accordance with an embodiment of the invention;

FIG. 7 is a schematic top view of a PV module having a hexagonal support member, in accordance with an embodiment of the invention; and

FIG. 8 schematically illustrates the use of edge clips in the PV module of FIG. 6, in accordance with an embodiment of the invention.

### DETAILED DESCRIPTION OF THE INVENTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed in practicing the invention.

The term “photovoltaic cell,” as used herein, refers to a device or a component of a device that is configured to generate electricity upon exposure to light. A photovoltaic cell can include one or more layers that individually, or collectively, define a photoactive material. For instance, a photoactive material can include a p-n junction. A photoactive material can be a Group V or Group III-V semiconductor. In some examples, a PV cell can include CdTe, copper indium gallium diselenide (CIGS), copper zinc tin sulfide (CZTS), copper zinc tin selenium (CZTSe), or silicon (e.g., amorphous silicon).

The term “shingle,” as used herein, refers to a roof covering having individual elements that, in some cases, can overlap. Shingles can have flat rectangular shapes laid in rows from the bottom edge of a roof up, with each successive higher row overlapping joints in the row below. Shingle-like elements can have the functional attributes of shingles (e.g., directing water flow), but may be formed in a single-piece (or integrated) fashion. A shingle-like element can be a single-piece component that is patterned to resemble a shingle, such as having depressions (or troughs) that provide the functional attributes of individual overlapping elements, including, without limitation, directing water flow and preventing water build-up.

The invention provides photovoltaic (PV) modules for use in various settings, such as residential settings. Some embodiments provide PV modules that are configured for replacement of shingles on residential rooftops, or integration into roofing systems having shingles or like structures. In some embodiments, PV shingles are sized and shaped to replace, or be used in conjunction with, roof shingles currently available. This advantageously enables the integration of the functionality of current roof shingles (e.g., directing water flow) with that of PV cells (e.g., power generation).

Shingle-like PV modules (also “PV shingles” herein) provided herein can be functionally similar, if not identical, to non-PV shingles, such as standard roof coverings. PV shingles can have the look and feel of non-PV shingles, such as the size, shape and color of non-PV shingles, and the functionality of PV modules having one or more PV cells. This advantageously enables PV shingles of the invention to replace non-PV shingles, thereby enabling power generation, while simultaneously providing the function of a standard shingle, or integration into a roofing system having PV shingles and, in some cases, non-PV shingles.

### Solar Modules

An aspect of the invention provides a photovoltaic (PV) module (also “PV shingle” herein) comprising a first layer of a transparent material that is transparent to at least a portion of incident light, and a second layer of a water vapor barrier material adjacent to the first layer. The second layer is transparent to at least a portion of light from the first layer. The PV module includes a third layer having one or more interconnected photovoltaic (PV) cells adjacent to the second layer. The one or more interconnected PV cells generate power upon exposure to light from the second layer. A fourth layer of an electrically insulating material is adjacent to the third layer. The first layer includes one or more outer surfaces that are oriented at an angle greater than zero degrees in relation to a surface of the second layer adjacent to the first layer.

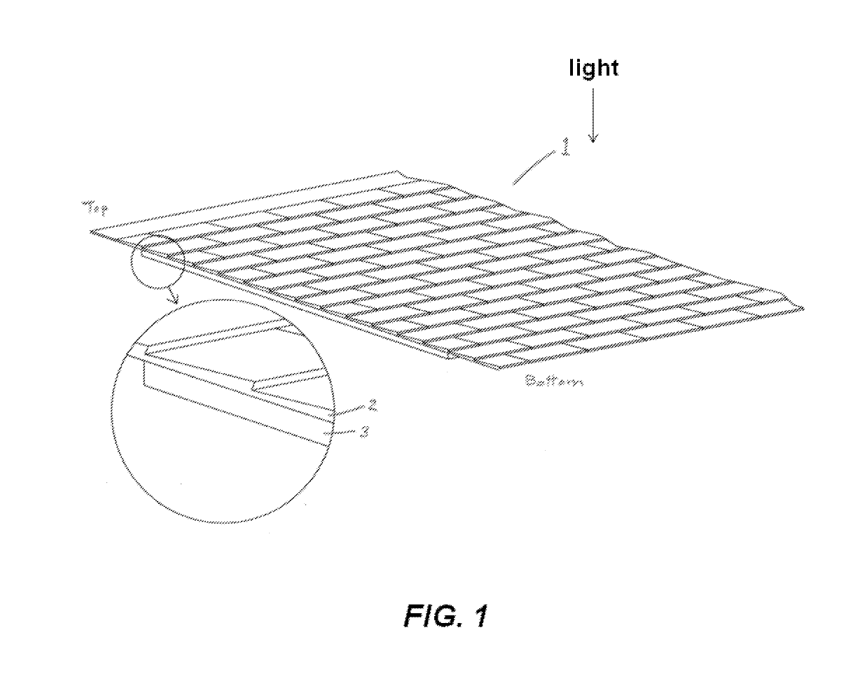

In some embodiments, the first layer includes one or more outer surfaces that are structured to provide shingle-like functionality. Such functionality can include accepting water and directing the flow of water towards ground, in addition to minimizing the build-up of water. In some cases, the one or more outer surfaces include depressions or troughs, in addition to ridges, that are provided in a pattern to provide such shingle-like functionality (see, e.g., FIG. 1). Such pattern can facilitate the flow of water from a high point to a low point (with respect to ground), and also aid in minimizing, if not preventing, the build-up of water, such as rainwater incident on a roof having the PV module.

A pattern of depressions or troughs can be formed with the aid of embossing, such as, for example, using a roller (or die) to imprint a shingle pattern in a layer of a polymeric material (e.g., poly(methyl methacrylate)). Embossing is a process for producing raised or sunken designs or relief in a substrate (e.g., a sheet of a polymeric material). In some cases, embossing can be implemented with the aid of matched male and female roller dies, or by passing sheet or a strip of a substrate material between rolls of the desired pattern. In some situations, a sheet of a polymeric material, such as poly(methyl methacrylate) (PMMA), can be cast onto an embossed mold.

In some embodiments, the first layer is adapted to be the outermost layer of the PV module. In cases in which the PV module is provided on a roof with other non-PV shingles, the outermost layer is configured to give the functionality of non-PV shingles, while remaining transparent to at least a portion of incident light. At least a portion of light incident on the first layer can thus pass through the first layer and reach the one or more PV cells, which can enable power generation.

The first layer in some embodiments is adapted to withstand mechanical stresses, such as from wind or objects directly striking the first layer. The first layer can thus protect the PV module from damage or degradation when installed on a roof or other structure.

The layers can be joined to one another with the aid of chemical or mechanical fasteners. An example of a chemical fastener is an adhesive that can be provided between adjacent layers to secure them together. An example of a mechanical fastener is a nail or screw that secures adjacent layers or a stack of layers together. For instance, the PV module can include multiple screws at its periphery to secure the layers together with the aid of a compressive force provided by securing the screws to the PV module.

The first layer can be formed of a polymeric material, such as polymethyl methacrylate. The polymeric material can be resistant to ultraviolet radiation. That is, upon exposure to UV radiation, the material comprising the first layer does not appreciably decay over a predetermined period of time, such as at least 1 day, 10 days, 1 month, 12 months, 1 year or more.

The water vapor barrier material is formed of a material that has a low or substantially low water vapor permeance. In some situations, the water vapor barrier material has a water vapor permeance less than or equal to about 300 ng/s·m²·Pa, 200 ng/s·m²·Pa, 100 ng/s·m²·Pa, 10 ng/s·m²·Pa, 3 ng/s·m²·Pa, 1 ng/s·m²·Pa, or 0.3 ng/s·m²·Pa. In some cases, the water vapor barrier material has a permeance from about 10⁻⁶ grams/m²/day to 10⁻³ grams/m²/day, or about 10⁻⁵ grams/m²/day to 10⁻⁴ grams/m²/day. In some situations, the water vapor barrier material is formed of a polymeric material, such as a coated polymeric material (e.g., polyethylene terephthalate or polyethylene naphthalate), a metal, or an oxide, such as a silicon oxide, SiOₓ, wherein ‘x’ is a number greater than zero. The water vapor barrier material comprising the second layer is transparent to at least a portion of light directed to the second layer from the first layer.

In some embodiments, at least a portion of the one or more outer surfaces of the PV module are roughened in relation to the surface of the second layer. This can provide a light coupling structure in the first layer which can couple light from an environment external to the PV module and into the first layer.

In some situations, the PV module further includes a fifth layer of a water vapor barrier material adjacent to the fourth layer. The water vapor barrier material of the fifth layer can include a polymeric material (or polymeric substrate), a metal oxide, or a metal, such as, for example, aluminum. In an example, the fifth layer includes a polymeric substrate coated with one or more barrier layers, such as one or more metal oxide layers. In some situations, the water vapor barrier material of the fifth layer has a water vapor permeance less than or equal to about 300 ng·m²·Pa, 200 ng/s·m²·Pa, 110 ng/s·m²·Pa, 10 ng/s·m²·Pa, 3 ng/s·m²·Pa, 1 ng/s·m²·Pa, or 0.3 ng/s·m²·Pa. In some cases, the water vapor barrier material of the fifth layer has a permeance from about 10⁻⁶ grams/m²/day to 10⁻³ grams/m²/day, or about 10⁻⁵ grams/m²/day to 10⁻⁴ grams/m²/day.

In some cases, the PV module further includes a sixth layer of a protective material which is adapted to guard or protect the fifth layer against damage during shipping and/or installation of the PV module. The protective material can be formed of a metallic material (e.g., stainless steel or aluminum plate), polymeric material or composite material.

PV modules can be secured to one another with the aid of a chemical or mechanical fastener. For instance, a first PV module can be secured against a second PV module using an adhesive layer at an underside of the first PV module and a top side of the second PV module. In an example, the adhesive is applied to the sixth layer of the first PV module and a side portion of the first layer of the second PV module. As an alternative, mechanical fasteners can be used to secure the first PV module to the second PV module.

Chemical and/or mechanical fasteners can be used to secure PV modules to structures on which they are to be mounted, such as a roof or other support structure that is adapted to come in view of a source of electromagnetic radiation, such as the sun. In an example, a chemical fastener, such as an adhesive, is applied to an underside of a PV module, which is subsequently applied to a surface, such as a roof. In another example, a mechanical fastener, such as a screw or nail, is used to secure a PV module to a surface, such as a roof.

The PV module includes functionality that enables its integration into support structures, such as roofing structures. Roofing structures can be angled in relation to a horizontal surface. Roofing structures in some cases can include a wooden or metallic surface on which shingles can be provided with the aid of fasteners, such as chemical or mechanical fasteners.

In some embodiments, a PV module includes one or more outer surfaces that are angled in order to facilitate the flow of water along the PV module and along the direction of the gravitational acceleration vector, and in some cases to facilitate the introduction of light into the PV module, which can aid in optimizing power generation. In some embodiments, the PV module includes one or more outer surfaces. Each of the outer surfaces can be oriented at an angle greater than zero degrees in relation to the surface of the second layer adjacent to the first layer. In some examples, an outer surface is oriented at an angle greater than or equal to about 0°, 0.1°, 0.2°, 0.3°, 0.4°, 0.5°, 0.6°, 0.7°, 0.8°, 0.9°, 1°, 2°, 3°, 4°, 5°, 6°, 7°, 8°, 9°, 10°, or 20°, or in some cases between about 0° and 2°, or 1° and 1.5°.

In some cases, the one or more outer surfaces of the PV module are formed to include a pattern of features (e.g., depressions or troughs) to provide a shingle-like functionality. Such pattern of features can facilitate the flow of water along the PV module, thereby minimizing the build-up of water.

In some embodiments, the PV module includes one or more outer surfaces that are structured to provide shingle-like functionality. The outer surfaces are adapted to receive light and direct at least a portion of the received light to one or more PV cells of the PV module. In some cases, the one or more outer surfaces include depressions or troughs that are provided in a pattern to provide such shingle-like functionality (see, e.g., FIG. 1). Shingle-like features can be formed by embossing a pattern of depressions or troughs in a layer of a polymeric material (e.g., poly(methyl methacrylate)), for example.

In some embodiments, the outer surfaces of the PV module are integrated with the first layer. For instance, the outer surface can be unitary (or single-piece) with the first layer. In some cases, the first layer can be manufactured to have one or a plurality of outer surfaces that are angled, as described above.

In cases in which the first layer includes a plurality of outer surfaces, the outer surface can be parallel to one another. For instance, a first outer surface can be parallel to a second outer surface. This can enable uniformity in shape and function of the PV module, as outer surface that are parallel to one another can facilitate a uniform flow of water (or other liquid).

In some embodiments, the PV module has a non-uniform thickness along an axis oriented from a first end to a second end of the photovoltaic module. In an example, the PV module has a non-uniform thickness by having a first layer with outer surfaces that are angled in relation to a surface of the second layer adjacent to the first layer.

Reference will now be made to the figures. It will be appreciated that the figures, including parts and structures therein, are not necessarily drawn to scale.

FIG. 1 is a perspective view of a PV module 1 having a shingle-like appearance, in accordance with an embodiment of the invention. The direction of incoming light (e.g., sunlight) is indicated in the figures. The indicated shingle-like features shown in the PV module 1 can be similar in size and appearance to those of typical roofing shingles. The PV module 1 can have a length and width of about 8 feet×4 feet, respectively, though other lengths and widths are possible. In some embodiments, the PV module 1 can have a length greater than or equal to about 1 feet, 2 feet, 3 feet, 4 feet, 5 feet, 6 feet, 7 feet, 8 feet, 9 feet, 10 feet, or larger, and a width greater than or equal to about 1 feet, 2 feet, 3 feet, 4 feet, 5 feet, 6 feet, 7 feet, 8 feet, 9 feet, 10 feet, or larger. In some situations, the dimensions of the PV module 1 are selected such that the PV module 1 can be readily installed with reduced or minimized cost.

In some embodiments, the PV module 1 is constructed of thin and light weight materials and without the use of a frame. The PV module 1 can be lighter than some conventional modules on an equal area basis. The PV module 1 has a “top” and “bottom” edge with the top portion being higher on the roof than the bottom portion so that water can flow off the roof in the direction of a vector oriented from the top to the bottom, in a manner similar to ordinary shingles on a pitched roof. The inset to FIG. 1 shows an enlarged portion of the PV module 1. The PV module 1 comprises a second section (or layer) 2 that includes a transparent molded sheet of an ultraviolet radiation (UV) resistant material. In an example, the UV resistant material is a polymeric material, such as poly(methyl methacrylate) (PMMA). The PV module 1 includes shingle-like molded ridges, in some cases with a maximum thickness from about one-eighth of an inch to a quarter of an inch. The molded ridge edges can be darkened or colored to provide contrast with adjacent material or roofing components, which can aid in enhancing the shingle look. Such contrast can functionally aid in installing the PV module 1, as the difference in contrast can aid in setting the PV module on a support surface.

The PV module 1 can have a pattern of depressions (or troughs) that provide shingle-like functionality. The pattern can be formed by embossing the depressions in the material of the second section 2. The pattern can include alternating lines (as depressions) formed in a surface of the material of the second section 2, such as perpendicular lines when viewed from the direction of entry of sunlight.

The PV module 1 includes a third section (or layer) 3 that includes active photovoltaic material and, in some cases, encapsulating materials, which include a plurality of layers. The third section 3 can include a plurality of layers (or sub-layers). The third section 3 can include one or more photovoltaic cells that are each configured to generate electricity upon exposure to light. The PV cells in some cases are thin film PV cells. In some examples, the PV cells include CdTe, copper indium gallium diselenide (CIGS), copper zinc tin sulfide (CZTS), copper zinc tin selenide (CZTSe), or amorphous silicon PV active materials, though other photoactive materials (absorbers) can be used.

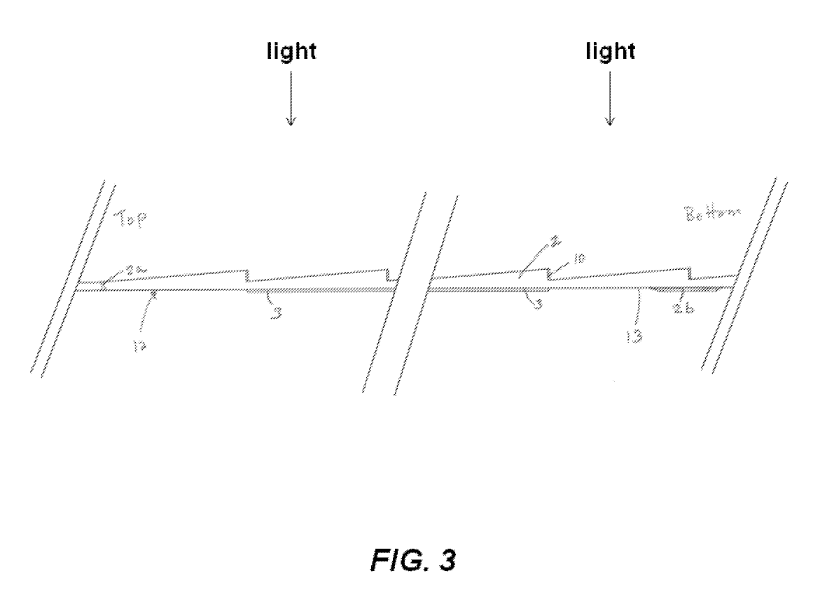

The third section 3 can have various sizes and shapes. In some embodiments, the third section 3 substantially covers the second section 2. In other embodiments, the third section 3 does not substantially cover the second section 2 (see FIG. 3). The third section 3 can have a thickness that is less than a thickness of the second section 2. In some situations, the thickness of the third section 3 is from about 200 microns to 5 mm, or 300 microns to 1 mm.

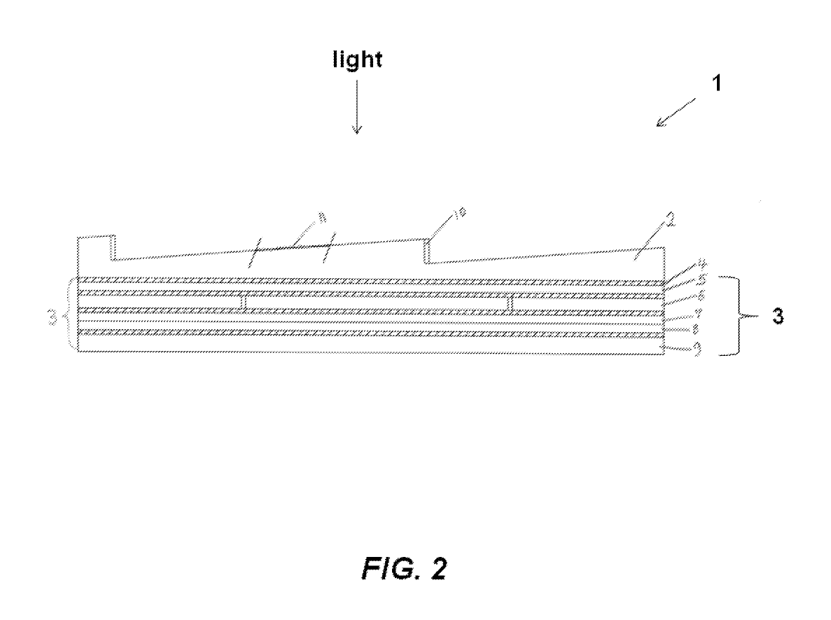

FIG. 2 is a schematic side view of the PV module 1, in accordance with an embodiment of the invention. The thickness of the third section 3 has been exaggerated in relation to the thickness of the second section 2 to illustrate the component layers of the third section 3. Layers of the second section 2 are bonded together with the aid of an adhesive layers 4. The adhesive layers 4 can each have a thickness be from about 0.001 inches to 0.01 inches. The adhesive layers 4 can have different thicknesses and compositions from one another. The adhesive layers 4 through which incoming light propagates to the PV cell(s) can be at least partially transparent to light; other hatched layers 4, however, need not be transparent to light. The third section 3 includes a moisture barrier layer 5 on the light receiving side of the PV module 1 (i.e., side facing the direction of incoming light). In some cases the moisture barrier layer 5 is a transparent layer of a polymeric material upon which has been deposited a transparent thin film or series of films which can aid in blocking moisture from reaching the PV cells of the PV module. The polymeric material can be polyethylene terephthalate (PET) or polyethylene naphthalate (PEN). As an alternative, the moisture barrier layer 5 can be a thin layer of glass, which can be formed on glass float lines. In some cases thin glass can be pre-bonded to the second section 2 in order to aid in handling sheets of thin glass.

The PV module 1 further includes a layer of photoactive material 6, which comprises one or more PV cells that are configured to generate electricity upon exposure to light directed from the second section 2 and through the moisture barrier layer 5. The layer of photoactive material 6 can include a single solar cell or a plurality of electrically interconnected solar cells, such as thin film cells deposited on a thin metal foil substrate (for example, stainless steel substrate), or a thin polymer substrate. In some cases, the one or more PV cells of the layer of photoactive material 6 comprise CdTe, CIGS, CZTS, CZTSe, or amorphous silicon photoactive materials.

The PV module 1 includes a layer of an electrically insulating material 7 that aids in keeping any voltage generated by the PV cell(s) of the layer of photoactive material 6 contained within the layer of photoactive material 6. The layer of the electrically insulating material 7 comprises an electrically insulating material, such as a dielectric. In an example, the layer of the electrically insulating material 7 includes an oxide (e.g., metal oxide) or an electrically insulating polymeric material or composite material having a ceramic substance. The layer of the electrically insulating material 7 is situated behind the cell(s) and away from the second section 2. In some cases, the layer of the electrically insulating material 7 is formed of an optically transparent material, though in other cases it is formed of an optically opaque or partially transparent material.

The PV module 1 includes another moisture barrier layer 8 that includes a moisture barrier material situated at the back of the shingle-like module. The moisture barrier layer 8 can be a thin layer of aluminum foil or other low cost material that has a low water vapor transmission rate. The aluminum foil can be replaced with a thin barrier film, as can comprise the moisture barrier layer 5, with the polymer layer facing toward the outside (i.e., away from the layer of the electrically insulating material 7), and in some cases having a moisture barrier coating adjacent to the layer of the electrically insulating material 7.

In some cases it may be difficult to avoid shipping damage that may compromise the moisture integrity of the PV module 1 if the moisture barrier layer 8 is aluminum foil. In some cases the PV module 1 includes a protective layer 9 adjacent to moisture barrier layer 8. The protective layer 9 can be attached to the PV module 1 prior to shipment. The protective layer 9 can be formed of roofing felt (e.g., asphalt saturated felt), membrane roofing (e.g., poly(vinyl chloride)), or other polymeric material. The composition of layer 9 can depend upon how the roof is to be constructed. In some situations, layer 9 is a material other than fluoropolymer material, though in some cases a fluoropolymer material can be used.

The PV module 1 can include contrast darkening or coloring on the edges of the shingle, as illustrated by the darkened section 10. The second section 2 of the PV module 1 can have a conditioned surface 11, such as a roughened surface. The conditioned surface 11 can aid in reducing glare and keeping the PV module 1 from appearing shiny in comparison to non-PV (or non-electricity generating) shingles. In addition to reducing glare, this treatment can simultaneously provide an antireflection function, which can enable more light to reach the PV cells in the layer of photoactive material 6 of the PV module 1, such as by way of scattering. The conditioned surface 11 can be colored, but such coloration can be selected to not decrease PV cell performance. In such a case, the reflected light that comprises the color of the conditioned surface 11 is light that is not used by the PV cell(s) of the layer of photoactive material 6 to generate electricity. Consequently, for improved performance, the conditioned surface 11 in some cases is not colored.

The PV cell(s) of the layer of photoactive material 6 of the PV module 1 that absorb all of the available light can appear dark, such as dark grey. In some cases, the PV cell(s) can appear to have other colors. Such color configuration can be compatible with ordinary roofing shingles, enabling the PV module 1 to be installed with non-PV shingles.

FIG. 3 shows an expanded view of the top and bottom regions of the shingle-like PV module of FIGS. 1 and 2. The third section 3 containing the solar cells and the encapsulating layers is disposed below the second section and away from the direction of incoming light (e.g., sunlight). The PV module 1 includes areas 12 and 13 that extend past the third section 3 in order to provide flashing and water sealing of the roof. Although not depicted explicitly in the figures, a similar area can be provided on each side of the shingle-like module for flashing along each side. Along the area 12, ordinary shingles (i.e., non-PV shingles) can cover all or most of the corresponding region in the second section 2, but may not go past the edge of the third section 3 containing the active PV cell(s). This region can include holes 2a for nailing the PV module 1 to a roof. Similarly, along bottom area 13 the corresponding area of the second section 2 can cover the ordinary shingles. A region of adhesive 2b can be provided to stick the second section 2 to the upper covered portions of PV shingles or non-PV shingles. Along each edge (not shown) the ordinary shingles can cover and be sealed to the areas of the second section 2 that extend past the solar material of the third section 3. Between top, bottom, and edges of the PV module 1 additional adhesive can be used to secure the central regions of the PV module 1 to the roof. In some cases the entire PV module 1 can be attached (e.g., glued, fastened) to the roof and, in some cases, secured to other shingles.

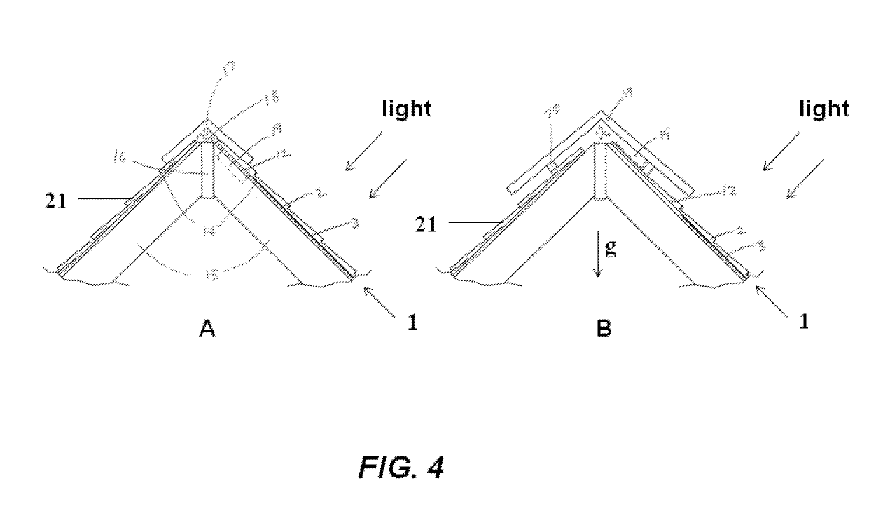

FIG. 4 is a schematic cross-sectional side view of two roof ridge lines, in accordance with an embodiment of the invention. In schematic A, sheets of roofing material 14 (e.g., plywood and felt) are attached to rafters 15 that are secured to a ridge beam 16. On the side with incoming light, as indicated by the arrows, the shingle-like PV module 1, having the second section 2 and third section 3, is installed, while the other side receives ordinary shingles 21. Alternatively, the roof of FIG. 4 has shingle-like PV modules on both sides. A ridge cap 17 provides a water seal while creating an open area at the apex where wiring 18 for the PV module 1 can be routed. The ridge cap 17 can be configured to not cause shading of the PV module 1, including the PV cell(s) in the third section 3. In some cases, a small cutout in roof sheeting 14 can provide room for mounting a junction box (J-box) 19 for the electrical connections to the PV module 1. A similar cutout can be provided for an electrical inverter so that wiring 18 can be entirely configured to transmit alternating current (AC). As an alternative, direct current can be transmitted. Schematic B of FIG. 4 is similar to schematic A, with the exception that the ridge cap 17 is larger in relation to that of schematic A, and extends over a portion of the roof with spacers 20. This allows staggered openings along the ridge line for venting an air space (or ventilation space) under the roof. Ventilation can be improved or otherwise enhanced with wind turbines or fans. In some cases, such ventilation can aid the PV cells(s) of the PV module 1 to run cooler on a hot day for improved power generation. In an example, the space provided by the roof spacers 20 draws air into the ventilation space, and the flow of air aids in cooling the PV cells(s) of the PV module 1. In some cases, the space under the ride cap 17 can provide space for mounting the J-box 19 and/or a small inverter, in addition to providing room for wiring, such as wiring to transmit power generated by the PV module 1 into an electrical grid and/or an energy storage unit (e.g., battery). In some embodiments, the wiring can be provided by way of a low profile box that sits on top of the roof and has the appearance of a roof vent.

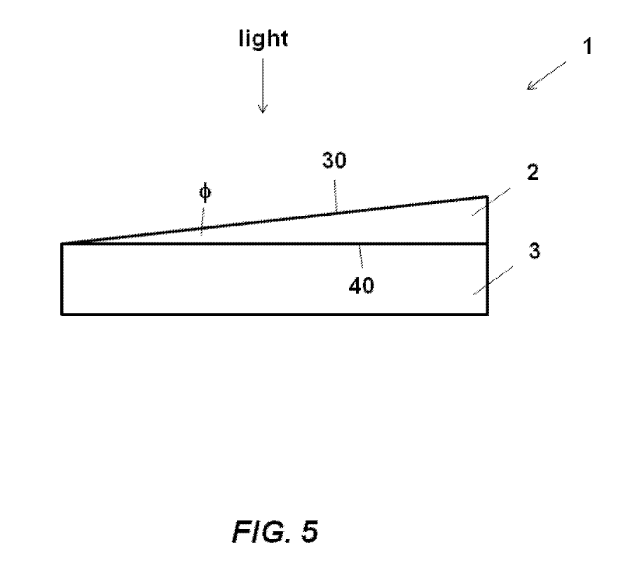

In some embodiments, shingle-like PV modules provided herein, such as the PV module of FIG. 1, have one or more outer surfaces (e.g., a single embossed outer surface) that are oriented at an angle greater than zero degrees in relation to a surface of the second layer adjacent to the first layer. With reference to FIG. 5, the PV module 1 includes an outer surface 30 of the second layer 2 and an inner surface 40 between the second section 2 and the third section 3. The PV module 1 can include one or a plurality of outer surfaces, such as at least 2, 3, 4, 5, 6, 7, 8, 9, 10, 20, 30, 40, 50 outer surfaces. The outer surface 30 is at an angle Φ in relation to the inner surface 40. In some cases, Φ is greater than or equal to about 0°, 0.1°, 0.2°, 0.3°, 0.4°, 0.5°, 0.6°, 0.7°, 0.8°, 0.9°, 1°, 2°, 3°, 4°, 5°, 6°, 7°, 8°, 9°, 10°, or 20°, or in some cases between about 0° and 2°, or 1° and 1.5°. The PV module 1 can have a non-uniform thickness along an axis parallel to the inner surface 40 and leading from one side of the PV module 1 to another. Such a configuration enables shingles to be laid adjacent to one another while permitting fluid flow from a first shingle to a second shingle that is elevated with respect to the first shingle. For instance, with the PV module 1 installed adjacent to a shingle (e.g., shingle-like PV module or non-PV shingle) on a roof that is angled with respect to a horizontal surface, water incident on the PV module 1 can flow along the direction of the gravitational acceleration vector (see FIG. 4, ‘g’) toward the shingle and ultimately to ground or a water collection system (e.g., trough). The angled shingle-like PV module 1 of FIGS. 1, 2 and 5 thus permits fluid flow from one shingle to another, while minimizing the trapping of water or other fluid.

In some embodiments, a shingle-like PV module can include a plurality of outer surfaces that are parallel to one another. In an example, the PV module of FIG. 1 includes two outer surfaces that are parallel to one another.

In some embodiments, a photovoltaic (PV) system (also “solar system” herein) can include a plurality of PV modules, each PV module having one or more PV cells for generating electricity. The PV modules can be electrically coupled to one another with the aid of a buss bar and other structure supports for securing the PV modules to a roof or other mounting structure. PV modules can be electrically coupled to one another in series and/or parallel. In some situations, shingle-like PV modules are used in conjunction with shingles that do not have PV modules (i.e., standard shingles). In an example, shingles from a section of a roof can be replaced with PV shingles for power generation to provide a roof having PV shingles intermixed with non-PV (or standard) shingles.

In some embodiments, float line glass technology can enable the preparation of substantially thin glass sheets of various sizes. Such technology, for instance, can enable the formation of glass sheets that are about 1 mm in thickness with dimensions up to about 1 meter by 1.8 meters. In other examples, such technology can enable the formation of glass sheets that are about 0.7 min in thickness with dimensions up to about 1.2 meters by 1.5 meters. Glass of 0.55 mm thickness can be prepared in smaller sizes, while slightly thicker glass can be made in larger sizes. Larger and thinner glass can enable the formation of larger and/or lighter conventional solar modules and shingle-like PV modules. In an example, a PV module formed with a top sheet of glass of 1 mm thickness and a back sheet of 0.7 mm glass, has a weight that is about 50% that of a current conventional PV module (without a frame) made with a single sheet of glass and a TAPE (Tedlar®, aluminum, polyester, EVA) back sheet. A thin glass-glass module can advantageously provide additional environmental protection, in particular for thin-film solar cells.

In some embodiments, glass-glass shingle-like PV modules are provided. In an example, for the PV module 1 of FIG. 2, the second section 2 is formed of glass and the moisture barrier layer 5 is formed of glass. A potential issue with such glass-glass configuration is the PV module 1 may not withstand the various mechanical loads required of a conventional module with aluminum framing, which can lead to structure defects, breakage and handling issues. In some cases, for a glass-glass shingle-like PV module, additional structural support can be provided with the aid of a support member, such as the hollow support members and mounting systems of U.S. patent application Ser. No. 13/347,383, filed Jan. 10, 2012 (“PHOTOVOLTAIC MODULES AND MOUNTING SYSTEMS”), which is entirely incorporated herein by reference.

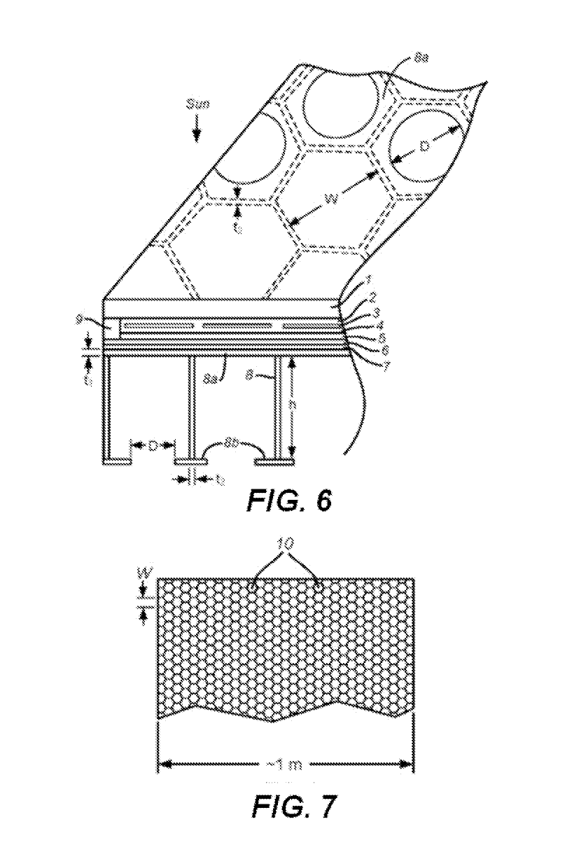

FIG. 6 schematically illustrates a photovoltaic (PV) module, in accordance with an embodiment of the invention. The PV module of FIG. 6 can be a thin laminated structure. The PV module of FIG. 6 can have a shingle-like configuration described herein, such as one or more outer surfaces that are angled with respect to an inner surface (see, e.g., FIG. 5). The PV module of FIG. 6 includes a layer of an optically transparent material 1, such as low iron tempered glass. The layer of the optically transparent material 1 is configured to permit light (hv) to enter the module. In an example, the layer of the optically transparent material 1 includes tempered glass having a thickness between about 1 mm and 5 mm, or 2 mm and 4 mm. The tempered glass in some cases is low iron tempered glass. In an example, the layer of the optically transparent material 1 has a thickness of about 3.2 mm. The module further includes an adhesive 2 and a photovoltaic (PV) cell layer 3. The PV cell layer 3 includes a plurality of PV cells, each of which can include CdTe, CIGS, CZTS, CZTSe or amorphous silicon PV active materials (or absorbers). In some cases, however, the PV cell layer 3 can include a single PV cell. The adhesive layer 2 is used to affix the PV cell 3 to the layer of the optically transparent material 1. The adhesive layer 2 can include ethylene vinyl acetate (EVA). The module further includes an adhesive layer 4, which can be formed of the same material as the adhesive layer 2. The adhesive layer 4 secures the PV cell 3 to a dielectric layer 5, which is disposed adjacent to a moisture barrier metal foil 6. The dielectric layer 5 can be formed of polyethylene terephthalate (PET) and metal foil layer 6 can be formed of aluminum, in some cases with a composition similar to TAPE. Alternatively, a thin dielectric film with moisture barrier properties deposited on a thin substrate can be used in place of the dielectric layer 5 and the metal foil layer 6.

With continued reference to FIG. 6, the PV module includes a support member disposed adjacent to a stack having the layers 1-6. In some cases, the support member has a plurality of through holes in a honeycomb configuration. Each individual hole is hexagonal in shape—that is, an individual hole is defined by an enclosure having six sides. The support member can be formed of a polymeric material, carbon fiber material, or composite material. The through holes can allow air to reach the PV cells(s) of the PV module, which can provide cooling that can aid in enhancing PV module performance (e.g., power output).

In the illustrated embodiment of FIG. 6, an adhesive layer 7 bonds an inner sheet 8a to the layers 1-6, and a hexagonal (honeycomb) support structure 8 is bonded to inner sheet 8a by way of a diffusion weld. Such a configuration can replace the relatively expensive “T” (Tedlar®) in the commonly used TAPE stack. In some cases, the support member 8 can be bonded to the inner sheet 8a with the aid of an adhesive or one or more mechanical fasteners, such as a screws, stables, or clamps.

In some cases, the inner sheet 8a is an inner sheet with thickness t1 and support structure 8 has webs of thickness t2, height h, and characteristic cell width (W). The support structure 8 and inner sheet 8a can be formed of a polymeric material, such as with the aid of injection molding methods. In an example, the support structure 8 and inner sheet 8a are formed by an injection molded part made from an economical polymer material, for instance polystyrene, polyethylene, polypropylene, polyvinyl chloride (PVC) or a material resistive to ultraviolet (UV) radiation. This can eliminate the need to join 8a and 8 with the aid of a weld.

The support structure 8 of FIG. 6 comprises through holes in various shapes and configurations, such as packing density. In an example, the through holes are in a honeycomb configuration, with each individual hole having six walls. The holes can have other geometrical shapes, such as, for instance, circles, triangles, squares, rectangles, pentagons, heptagons, or octagons. The through holes may be packed in a hexagonal close packing (hcp) configuration, though other packing arrangements, such as face centered cubic (fcc), may be used.

The parameters ‘t1’, ‘t2’, ‘h’, and ‘W’ can be adjusted depending upon the strength of the polymer material to give approximately the same stiffness as the sheet of glass it replaces. The stiffness can also be made to duplicate the stiffness of a conventional aluminum framed module, which may not be different from the case for glass. Web thickness ‘t2’ need not be the same as inner sheet thickness ‘t1’, although they may be. These thicknesses, ‘t1’ and ‘t2’, can be between about 0.01 inches and 1 inch, or 0.02 inches and 0.1 inches. Cell width ‘W’ can be between about 0.1 inches and 2 inches, or 0.5 inches and 1.5 inches, and web height ‘h’ can be between about 0.1 inches and 2 inches, or 0.5 inches and 1.5 inches. In some cases, the stiffness can be proportional to the cube of the thickness for a plate of material, and the useful thicknesses tend to fall in a fairly narrow range. To gain additional stiffness without adding substantial weight, an additional sheet 8b with thickness similar to ‘t1’ and ‘t2’ may be bonded to the back. This outer sheet can have openings (i.e., round holes) centered on the hex pattern with diameter ‘D’ to allow for convective heat loss from the module during solar exposure. The sheet 8b can be formed of a polymeric material or a metallic material, such as aluminum.

In the manufacturing of the PV module of FIG. 6, sheets of the various materials are stacked together along with an edge seal 9, and the materials are bonded together at an elevated temperature, in some cases under vacuum or in an inert environment (e.g., N₂, Ar or He). In some cases, the PV cell 3 is laterally bounded by the edge seal 9. The edge seal 9 can be a standalone component that is secured against the layers 2-5. Alternatively, the edge seal 9 can be formed as part of the inner sheet 8a or the support structure 8.

The support structure 8 of FIG. 6 can be formed in a mold, and the thickness parameters may also be varied locally a mold, template or panel used to form the support structure 8. For instance, any of the dimensions of support structure 8, even including web height ‘h’, can be changed to accomplish local strengthening at some positions. In some cases, the ‘h’ can be changed in the areas of module mounting where higher stresses may be encountered. These areas can be made more robust while low stress areas may be thinned, thus maximizing the overall stiffness for a given weight of material while adding strength at selected areas. In some cases, the thickness, ‘t1’ of inner sheet 8a contributes little to the stiffness of the support structure 8, since the loads are ultimately transferred to the glass by a sufficiently strong bond. In such cases, a thin inner sheet 8a can aid in achieving a reliable bond. The inner sheet 8a can be thinned to reduce weight. In some embodiments, the inner sheet 8a can be precluded if adequate bonding can be made between the cell walls of the support structure 8 and layer 6.

The support structure 8 and, if used, one or both of the inner sheet 8a and outer sheet 8b can define a support member of the PV module of FIG. 6. In some embodiments, one or both of the inner sheet 8a and outer sheet 8b are integral with the support structure 8. In some cases, the inner sheet 8a, support structure 8 and outer sheet 8b are formed as a single part. In other cases, the inner sheet 8a and support structure 8 are formed as a single part and the outer sheet 8b is secured against the support structure 8, such as with the aid of welding. In other cases, the support structure 8 and outer sheet 8b are formed as a single part, and the inner sheet 8a is secured against the support structure 8, such as with the aid of welding. This can be used in a case where the edges of the support structure 8 do not bond to layer 6 as well as they may bind to a similar structure or material as that of inner sheet 8a. The bond between the support structure 8 and layer 6 can be spread over the whole area of the module for better overall strength.

The support member can include holes extending through at least a portion of the support structure 8, in some cases extending through the entire support member. A hole can be defined by an enclosure, such as an enclosure having six walls in a hexagonal configuration. The enclosure is included in the support structure 8. An enclosure with a hole extending through at least a portion of the support structure 8 can be referred to as a “support cell.” The support cell is in fluid communication with a hole, such as a hole in the sheet 8b, that can provide fluid flow (e.g., air flow) for convective cooling of the PV cell 3. The strength of the support member, including the support structure 8, can be a function of the geometry of the support cell, including the size of the support cell. In some cases, a support member has from about 40 to 160 support cells per square foot, or 60 to 120 support cells per square foot, or 70 to 100 support cells per square foot. The square footage can be in relation to a cross-sectional area of the support member. In an example, a support member has 80 support cells per square foot. In some cases, the support cells are distributed in a side-by-side fashion. In some embodiments, the support cells are in a close packing arrangement, such as hexagonal close packing (hcp) or face centered cubic (fcc) arrangement. Each individual support cell can have a height that is less than or equal to the height (h) of the support structure 8.

The number density of support cells can inversely scale with the thickness of a wall of the support cell or the height (h) of the support structure 8. In an example, decreasing the support cell density can require an increase in the height of the support structure 8 or an increase in the thickness of one or more walls defining an enclosure of a support cell. In some cases, for a support structure formed of a polymeric material, the thickness is from about 1 inch to 3 inches, or 1.5 inches to 2.0 inches.

FIG. 7 is a schematic back view of a top section of a PV module, such as the PV module of FIG. 6 having a honeycomb support member. The PV module has a characteristic cell width (W). For a width of about 1.25 inches the PV module of FIG. 7 can have a module width of about one meter, as indicated. This can provide a PV module, including support member, with structural integrity that may be needed to resist wind loading and other environmental and handling issues. In some cases, if the width is doubled, the height (h) is scaled by a factor of about 2̂(⅓) (or about 1.26). For a module length of 1 meter by 1.6 meters, the overall module size can be about the same as that of conventional frame constructed silicon modules, but with lower cost and in some cases lower weight. The weight of the PV module can be less than a glass-glass design of equal size.

With continued reference to FIG. 7, the PV module includes one or more female plug receptacles 10 near the top of the module to provide electrical connections to the cells in the module. The plugs are shown as fitting within the cell dimension of the hexagonal structure, although other plug configurations are possible. The plugs can span a region where the web is removed (or not molded initially) and they need not be round in shape. The plugs 10 in some cases can have a male configuration.

In some examples, the PV module 1 of FIGS. 1 and 2 is formed in the manner described in the context of FIG. 6. The support structure of FIG. 6 can provide structural integrity to the PV module 1 of FIGS. 1 and 2, which can advantageously aid in minimizing, if not eliminating, handling and installation issues, such as material breakage. A shingle-like PV module having a support structure as described in the context of FIG. 6 can be lighter than conventional PV modules, enabling ease in transport and installation.

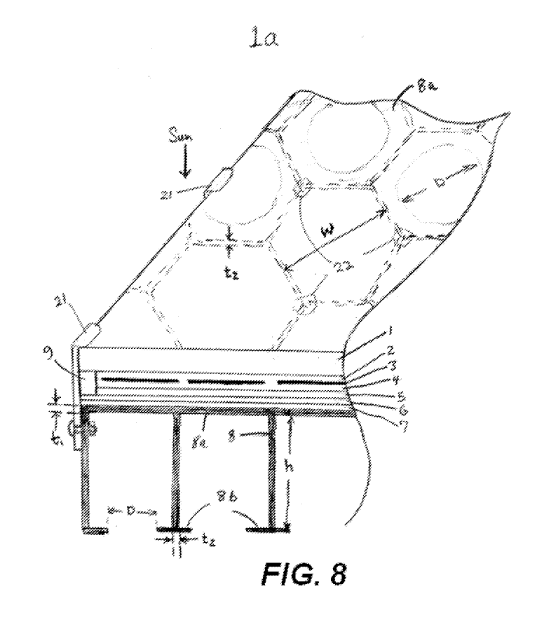

With reference to FIG. 8, the structure of FIG. 6 is attached to the honeycomb support structure 8 with the aid of edge clips 21 attached to the edges of the honeycomb support structure 8. The edge clips 21 are attached to the honeycomb support structure 8 with the aid of screws (shown) or by other attachment members or fasteners. Mechanical loading (e.g., wind, snow) on the top surface of the PV module of FIG. 8 can force the laminated structure against the strong honeycomb support, which may not lead to breakage. However, a wind load from the back may lift the center of the PV module of FIG. 8, which may lead to breakage or other rupture if only an edge restraint is used. Therefore, the PV module of FIG. 8 may include attachment positions 22 where the honeycomb cell walls intersect. The attachment positions 22 can include a chemical fastener to attach the structure of FIG. 6 to the honeycomb structure 8. In some cases, the chemical fastener is an adhesive. An attachment adhesive (like silicon rubber) may be selected to have properties that are suited to various weather conditions and be sufficiently flexible so as to relax under differential thermal loading. In some embodiments, the sheet 8a of the honeycomb structure either could be eliminated or configured (i.e., shaped, sized) to be similar to 8b without any loss of functionality. This is the reason that the small attachment positions 22 are shown at the intersections of the cell walls. In some cases, if sheet 8a is included in the PV module of FIG. 8, the adhesive attachment area could be much larger if required. Since the entire structural strength of the panel may reside in the honeycomb back sheet structure, very thin glass may be used in the lamination of the solar cells without compromising the water vapor barrier properties of the PV module. Such a configuration provides several benefits. For instance, the PV module can be proportionally lighter in weight, and the thinner glass has improved light transmission, thus improving the PV efficiency (i.e., power output upon exposure to light).

In some embodiments, shingle-like thermal collectors are provided. Shingle-like thermal collectors can have outer surfaces as described herein the context of shingle-like PV modules, but configured to capture thermal or radiant energy, which can be used, for example, in a Stirling engine.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

1. A photovoltaic module, comprising:
a first layer of an optically transparent material that is transparent to at least a portion of incident light;
a second layer of a water vapor barrier material adjacent to said first layer, wherein said second layer is transparent to at least a portion of light from said first layer;
a third layer having one or more interconnected photovoltaic (PV) cells adjacent to said second layer, wherein said one or more interconnected PV cells generate power upon exposure to light directed from said first layer through said second layer to said third layer; and
a fourth layer of an electrically insulating material adjacent to said third layer,
wherein said first layer includes one or more outer surfaces that are oriented at an angle greater than zero degrees in relation to a surface of the second layer adjacent to said first layer.

2. The photovoltaic module of claim 1, wherein said first layer comprises a polymeric material that is resistant to ultraviolet radiation.

3. (canceled)

4. The photovoltaic module of claim 1, wherein the layers are joined to one another with the aid of an adhesive.

5. The photovoltaic module of claim 1, wherein said water vapor barrier material comprises a coated polymeric material.

6. The photovoltaic module of claim 1, wherein said water vapor barrier material comprises SiOₓ, wherein ‘x’ is a number greater than zero.

7. The photovoltaic module of claim 1, wherein said moisture barrier material has a water vapor permeance less than or equal to about 10⁻⁴ grams/m²/day.

8. The photovoltaic module of claim 1, wherein at least a portion of said one or more outer surfaces are roughened in relation to said surface of said second layer.

9. The photovoltaic module of claim 1, further comprising a fifth layer of another water vapor barrier material adjacent to said fourth layer.

10. The photovoltaic module of claim 9, wherein said another water vapor barrier material comprises aluminum.

11. The photovoltaic module of claim 9, wherein said another water vapor barrier material comprises a polymeric substrate coated with one or more barrier layers.

12. The photovoltaic module of claim 9, further comprising a sixth layer of a protective material.

13. The photovoltaic module of claim 1, wherein said one or more outer surfaces are a plurality of outer surfaces that are integrated with said first layer.

14. The photovoltaic module of claim 1, further comprising a support member adjacent to said fourth layer, said support member having a plurality of holes extending through said support member.

15. The photovoltaic module of claim 1, wherein said one or more outer surfaces comprise a plurality of depressions.

16. A photovoltaic module, comprising:
a first layer of an optically transparent material that is transparent to at least a portion of incident light, said first layer having a pattern of depressions;
a second layer of a first moisture barrier material adjacent to said first layer, wherein said second layer is transparent to at least a portion of light from said first layer;
a third layer having one or more interconnected photovoltaic (PV) cells adjacent to said second layer, wherein said one or more interconnected PV cells generate power upon exposure to light from said second layer; and
a fourth layer of an electrically insulating material adjacent to said third layer.

17. (canceled)

18. The photovoltaic module of claim 16, further comprising a support member adjacent to said fourth layer, said support member having a plurality of holes extending through said support member.

19. A photovoltaic system, comprising one or more shingle-like photovoltaic modules, each shingle-like photovoltaic module of said one or more shingle-like photovoltaic modules having an embossed layer of optically transparent polymeric material adjacent to a layer of photoactive material configured to generate electricity upon exposure to light from said embossed layer.

20. The photovoltaic system of claim 19, further comprising a shingle adjacent to an individual shingle-like photovoltaic module of said one or more shingle-like photovoltaic modules.

21. The photovoltaic system of claim 19, wherein said embossed layer comprises a pattern of troughs in a shingle-like configuration.

22. A method for forming a shingle-like photovoltaic module, comprising providing a layer of photoactive material adjacent to an optically transparent polymeric sheet having a pattern of depressions formed therein in a shingle-like configuration, wherein said photoactive material generates electricity upon exposure to light from said optically transparent polymeric sheet.

23-24. (canceled)
